(19) United States
(12) Patent Application Publication
(10) Pub. No.: US 2008/0128916 A1
(43) Pub. Date: Jun. 5, 2008

(54) Semiconductor device including microstrip line and coplanar line

(75) Inventors: Koji Soejima, Kanagawa (JP); Masaya Kawano, Kanagawa (JP); Yoichiro Kurita, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/987,624

(22) Filed: Dec. 3, 2007

(30) Foreign Application Priority Data
Dec. 4, 2006 (JP) 327323/2006

(51) Int. Cl. H01L 23/48

(52) U.S. Cl. 257/777; 257/778; 257/E23.172

(57) ABSTRACT

Provided is a semiconductor device including an interconnect substrate, a transmission line which is formed on the interconnect substrate, and a circuit component which is mounted over the interconnect substrate and has a ground plane. The transmission line includes a first portion and a second portion that is connected to the first portion. The first portion and the ground plane constitute a microstrip line. The second portion and ground line constitute a coplanar line.

### BACKGROUND OF THE INVENTION

1. Field of the Invention

The present invention relates to a semiconductor device.

2. Description of the Related Art

JP 2003-282782 A discloses an interconnect substrate including a microstrip line. A transmission line for transmitting signals from an IC chip and a ground layer are provided to the interconnect substrate. The transmission line and the ground layer constitute the microstrip line.

Examples of related art documents which are pertinent to the present invention include JP 2001-035957 A and JP 2000-195988 A in addition to JP 2003-282782 A described above.

However, the transmission line and the ground layer which constitute the microstrip line are provided in different layers. Accordingly, the number of interconnect layers increases in the interconnect substrate. This causes an increase in a manufacturing cost of the interconnect substrate, resulting in the increase in the manufacturing cost of a semiconductor device provided therewith.

### SUMMARY OF THE INVENTION

According to the present invention, a semiconductor device having a semiconductor chip includes: an interconnect substrate including a main surface of the interconnect substrate; a transmission line which is provided on the main surface of the interconnect substrate; and a circuit component mounted over the main surface of the interconnect substrate and including a ground plane, and is characterized in that at least a part of the transmission line and the ground plane constitute a microstrip line.

In the semiconductor device of the present invention, the transmission line provided on the interconnect substrate and the ground plane provided in the circuit component constitute the microstrip line. Therefore, it is unnecessary to provide a ground plane, which constitutes the microstrip line, in the interconnect substrate. As a result, the number of interconnect layers of the interconnect substrate can be reduced.

According to the present invention, the semiconductor device suitable to decrease the number of interconnect layers of the interconnect substrate may be realized.

### BRIEF DESCRIPTION OF THE DRAWINGS

In the accompanying drawings:

FIG. 1 is a cross sectional view illustrating a semiconductor device according to a first embodiment of the present invention;

FIG. 2 is a plan view illustrating a part of an interconnect substrate shown in FIG. 1;

FIG. 3 is a cross sectional view illustrating a part of the semiconductor device shown in FIG. 1;

FIG. 4 is a cross sectional view illustrating a part of the semiconductor device shown in FIG. 1;

FIGS. 5A to 5C are process views illustrating an example of a method of manufacturing the semiconductor device shown in FIG. 1;

FIGS. 6A to 6C are process views illustrating the example of the method of manufacturing the semiconductor device shown in FIG. 1;

FIGS. 7A to 7C are process views illustrating the example of the method of manufacturing the semiconductor device shown in FIG. 1;

FIGS. 8A and 8B are process views illustrating the example of the method of manufacturing the semiconductor device shown in FIG. 1;

FIGS. 9A and 9B are process views illustrating the example of the method of manufacturing the semiconductor device shown in FIG. 1;

FIG. 10 is a cross sectional view illustrating a semiconductor device according to a second embodiment of the present invention;

FIGS. 11A and 11C are process views illustrating the example of the method of manufacturing the semiconductor device shown in FIG. 10;

FIG. 12 is a cross sectional view illustrating a semiconductor device according to a third embodiment of the present invention;

FIG. 13 is an explanatory cross sectional view illustrating a modified example of the semiconductor device according to the embodiment of the present invention;

FIG. 14 is an explanatory cross sectional view illustrating a modified example of the semiconductor device according to the embodiment of the present invention;

FIG. 15 is an explanatory cross sectional view illustrating a modified example of the semiconductor device according to the embodiment of the present invention;

FIG. 16 is an explanatory cross sectional view illustrating a modified example of the semiconductor device according to the embodiment of the present invention;

FIG. 17 is an explanatory cross sectional view illustrating a modified example of the semiconductor device according to the embodiment of the present invention;

FIG. 18 is an explanatory cross sectional view illustrating a modified example of the semiconductor device according to the embodiment of the present invention;

FIGS. 19A to 19C are explanatory plan views illustrating modified examples of the semiconductor device according to the embodiment of the present invention;

FIGS. 20A to 20C are explanatory plan views illustrating modified examples of the semiconductor device according to the embodiment of the present invention;

FIGS. 21A to 21C are explanatory plan views illustrating modified examples of the semiconductor device according to the embodiment of the present invention;

FIG. 22 is an explanatory cross sectional view illustrating a modified example of the semiconductor device according to the embodiment of the present invention;

FIG. 23 is an explanatory cross sectional view illustrating a modified example of the semiconductor device according to the embodiment of the present invention;

FIG. 24 is an explanatory cross sectional view illustrating a modified example of the semiconductor device according to the embodiment of the present invention;

FIG. 25 is an explanatory cross sectional view illustrating a modified example of the semiconductor device according to the embodiment of the present invention;

FIG. 26 is an explanatory cross sectional view illustrating a modified example of the semiconductor device according to the embodiment of the present invention; and

FIG. 27 is a plan view illustrating a part of an interconnect substrate shown in FIG. 13.

### DETAILED DESCRIPTION OF THE PREFERRED EMBODIMENT

Hereinafter, a semiconductor device according to a preferred embodiment of the present invention will be described in detail with reference to the accompanying drawings. In the description of the drawings, the same elements are expressed by the same reference numerals and thus the duplicated description is omitted.

### First Embodiment

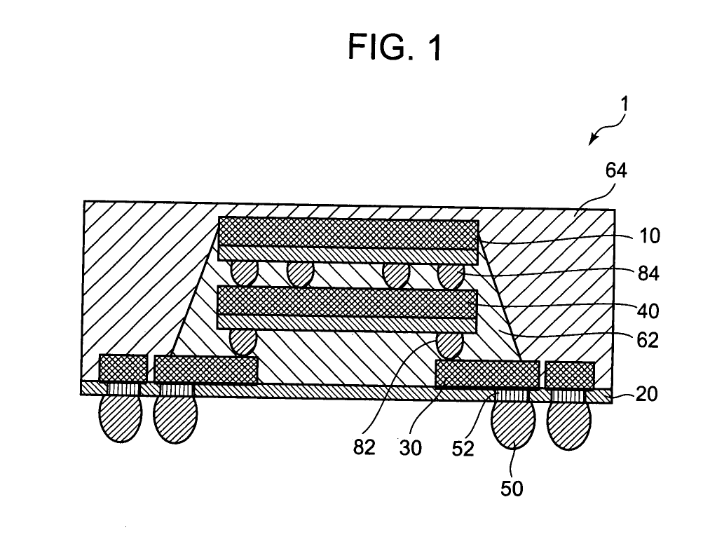

FIG. 1 is a cross sectional view showing a semiconductor device according to a first embodiment of the present invention. A semiconductor device 1 is a ball grid array (BGA) package which includes a semiconductor chip 10, a package substrate (interconnect substrate) 20, transmission lines 30, and a dummy chip (circuit component) 40. The transmission lines 30 are provided on an upper surface (first main surface) of the package substrate 20. The transmission lines 30 are used to transmit signals from the semiconductor chips 10. The transmission lines 30 are impedance-matched.

The dummy chip 40 is mounted on the upper surface of the package substrate 20 through flip-chip bonding. In other words, the dummy chip 40 is mounted on the upper surface of the package substrate 20 through conductive bumps 82. The conductive bumps 82 are connected with the transmission lines 30. A gap between the dummy chip 40 and the package substrate 20 is filled with an underfill resin 62. In this specification, the dummy chip is a chip in which an active element such as a transistor are not formed. A passive element such as a capacitive element or a resistive element may be formed in the dummy chip.

The semiconductor chip 10 is mounted on the dummy chip 40 through flip-chip bonding. In other words, the semiconductor chip 10 is mounted on a rear surface of the dummy chip 40 through conductive bumps 84. A gap between the semiconductor chip 10 and the dummy chip 40 is filled with the underfill resin 62. A seal resin 64 is provided to cover the semiconductor chip 10 and the dummy chip 40.

A lower surface (second surface) of the package substrate 20 is connected with solder balls 50 (external electrode terminals). The solder balls 50 are electrically connected to the transmission lines 30 through conductive plugs 52 extending through the package substrate 20.

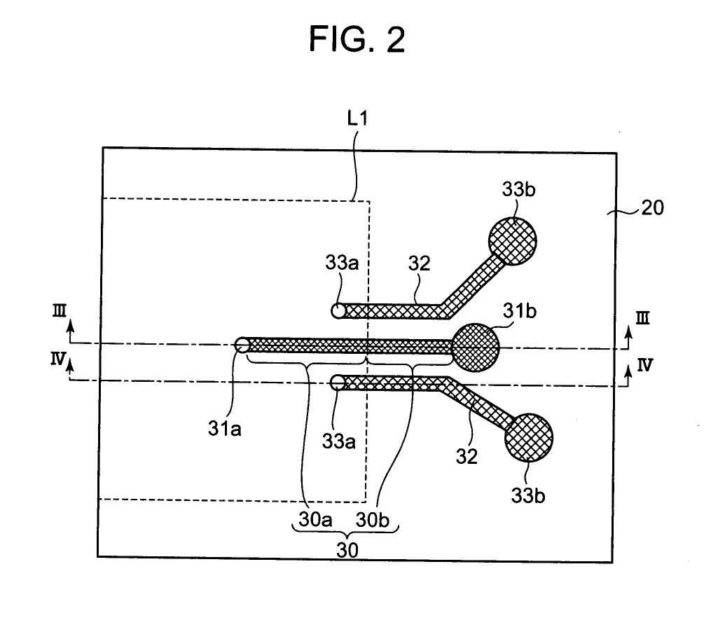

FIG. 2 is a plan view showing a part of the package substrate 20. In FIG. 2, an outer shape of the dummy chip 40 is expressed by a dotted line L1. The transmission line 30 includes a portion 30a for a microstrip line (first portion) and a portion 30b for a coplanar line (second portion). The portions 30a and 30b are connected with each other. In other words, one of the microstrip line and the coplanar line is changed to the other in the middle of the transmission line 30.

The portion 30b and ground lines 32, which is provided on the upper surface of the package substrate 20, constitute the coplanar line. The transmission line 30 further includes a connection portion 31a with respect to one of the conductive bumps 82 and a connection portion 31b with respect to one of the conductive plugs 52. Each of the ground lines 32 includes a connection portion 33a with respect to another one of the conductive bumps 82 and a connection portion 33b with respect to another one of the conductive plugs 52.

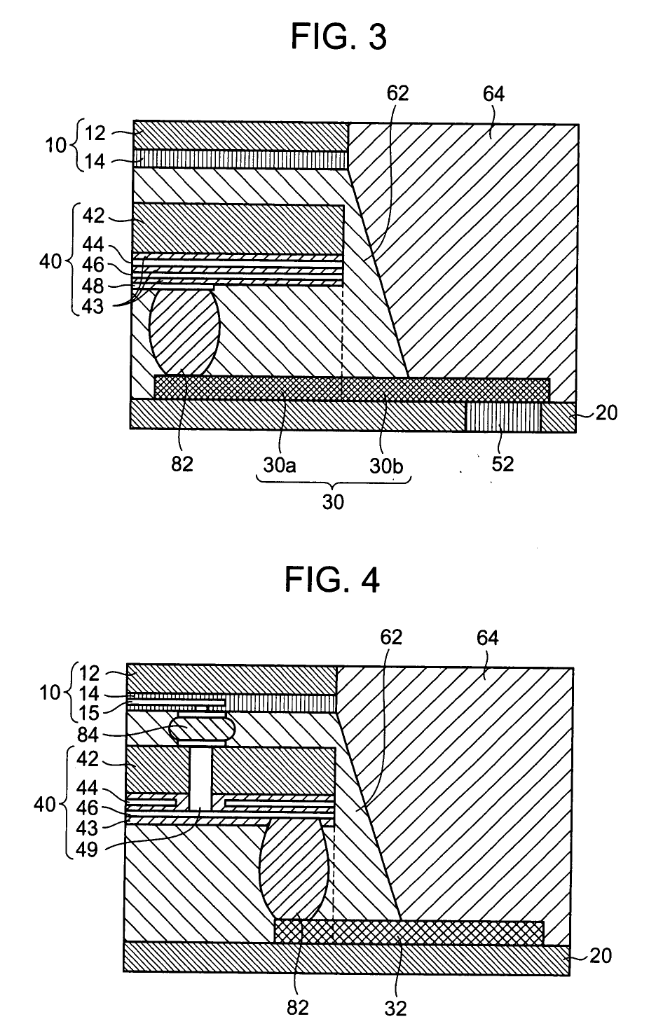

FIGS. 3 and 4 are cross sectional views showing a part of the semiconductor device 1. FIGS. 3 and 4 correspond to a cross section along a III-III line of FIG. 2 and a cross section along a IV-IV line of FIG. 2, respectively. As shown in FIG. 3, the dummy chip 40 includes a silicon substrate 42, insulating layers 43, a power supply plane 44, a ground plane 46, and a signal line 48. Each of the power supply plane 44, the ground plane 46, and the signal line 48 is provided to a corresponding one of the insulating layers 43 different from one another which are formed on the silicon substrate 42.

The portion 30a of the transmission line 30 and the ground plane 46 constitute the microstrip line. Therefore, a ground plane and ground lines are not provided above the lower surface of the package substrate 20. The ground plane 46 faces to only the portion 30a. The signal line 48 is connected with the transmission line 30 through the conductive bump 82. The semiconductor chip 10 includes a silicon substrate 12 and an interconnect layer (layer containing interconnect and insulating layer) 14 in which an LSI circuit is formed.

As shown in FIG. 4, the dummy chip 40 further includes a through electrode 49 extending through the silicon substrate 42, which is formed therein. The ground plane 46 is electrically connected to a ground interconnect 15 of the interconnect layer 14 through the through electrode 49 and one of the conductive bumps 84. The ground plane 46 is electrically connected to one of the ground lines 32 through the conductive bump 82.

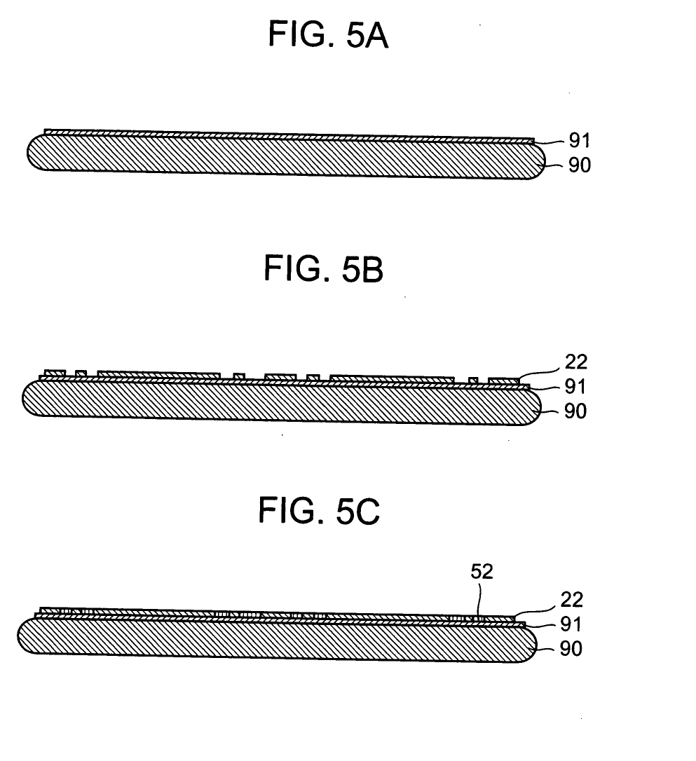

An example of a method for manufacturing the semiconductor device 1 will be described with reference to FIGS. 5A to 5C, 6A to 6C, 7A to 7C, 8A and 8B, and 9A and 9B. A seed film 91 is formed on a support substrate 90 (FIG. 5A). As the support substrate 90, for example, a silicon wafer can be used. The seed film 91 can be formed by, for example, forming a Ti film and a Cu film by a sputtering method. An insulating film 22 which will be contained in the package substrate 20 is formed on the seed film 91 and then patterned (FIG. 5B). The insulating film 22 is preferably made of a photosensitive resin such as a photosensitive polyimide resin or a photosensitive epoxy resin. After that, a layer of metal is grown in each opening portion of the patterned insulating film 22 by plating. The metal is preferably Cu or Ni. Therefore, the conductive plugs 52 are formed (FIG. 5C).

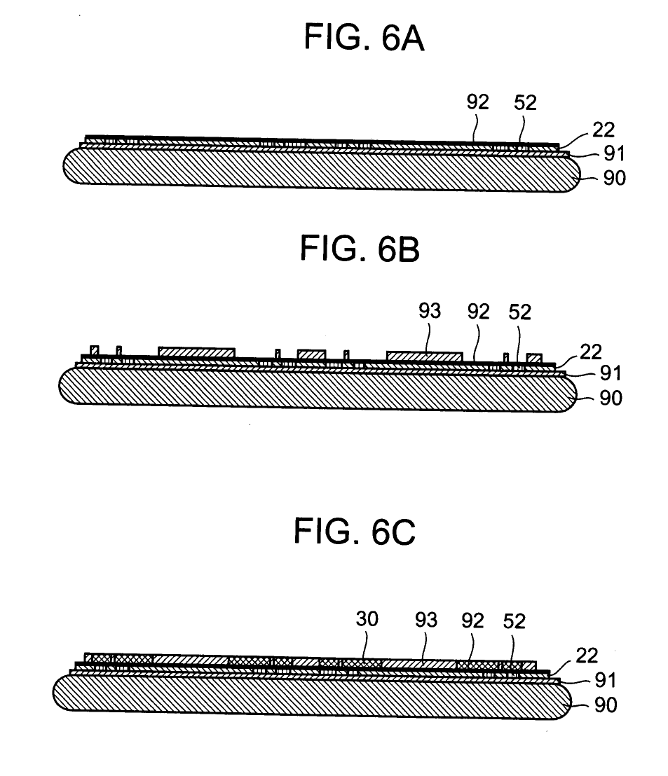

Next, a seed film 92 is formed on the insulating film 22 and the conductive plugs 52 (FIG. 6A). Then, a photoresist 93 is formed on the seed film 92 and patterned (FIG. 6B). After that, a layer of metal is grown in each opening portion of the patterned photoresist 93 by plating. The metal which can be used is Cu, Ni, Au, Pd, Pt, Ag, or the like. Therefore, the transmission lines 30 and the ground (GND) lines 32 (not shown) are formed (FIG. 6C).

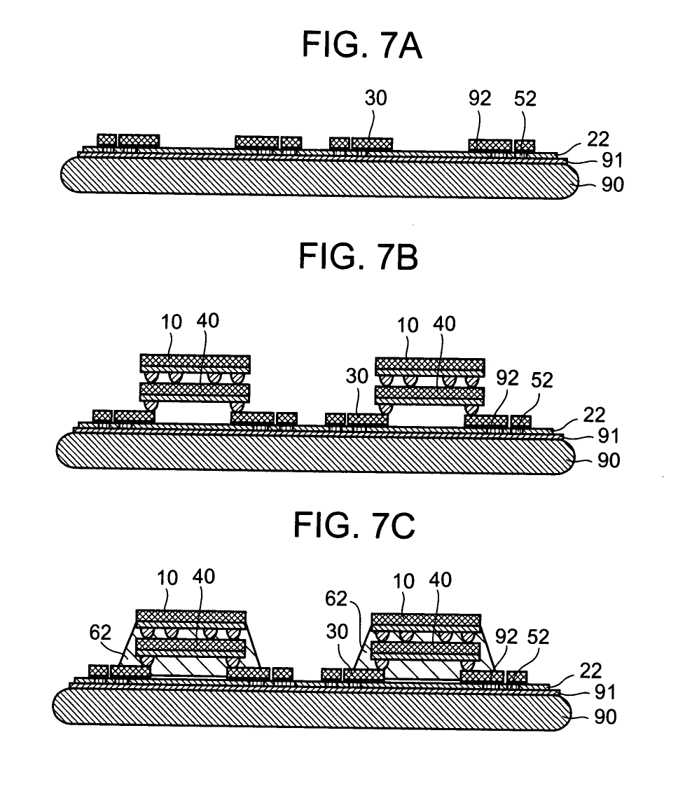

After the photoresist 93 is removed, a part of the seed film 92, in which the transmission lines 30 and the ground (GND) lines 32 (not shown) are not formed, is removed by etching (FIG. 7A). Then, the dummy chip 40 and the semiconductor chip 10 are flip-chip mounted in the stated order (FIG. 7B). An example is described in which the single semiconductor chip 10 is stacked on the dummy chip 40. However, the plurality of semiconductor chips may be stacked on the dummy chip 40 (Third Embodiment) After that, a lower portion the dummy chip 40 and a lower portion of the semiconductor chip 10 are filled with the underfill resin 62 (FIG. 7C). As the underfill resin 62, for example, an epoxy resin containing a silica filler can be used.

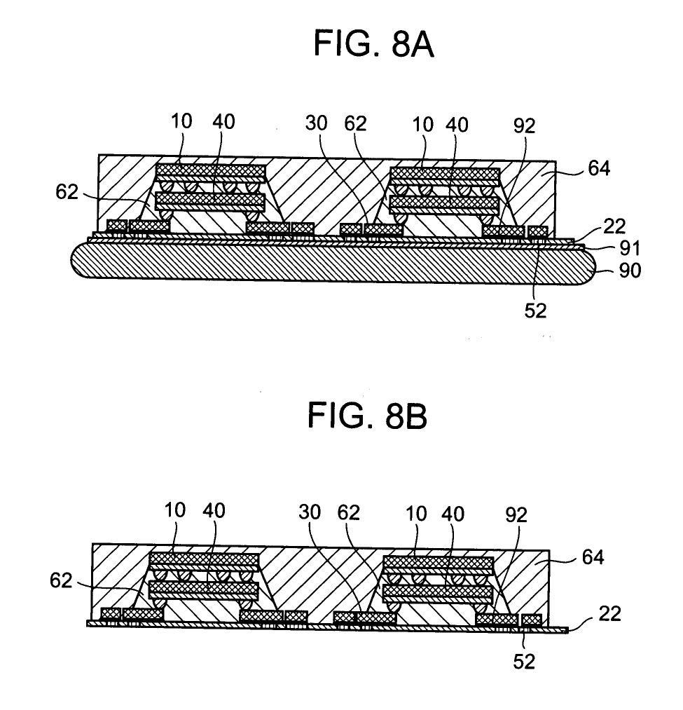

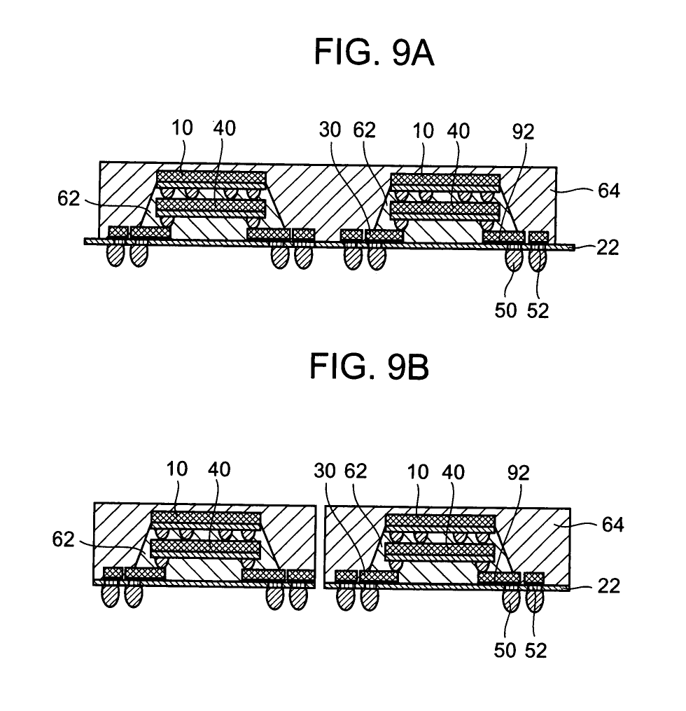

Next, the seal resin 64 is formed so as to cover the semiconductor chip 10 and the dummy chip 40 (FIG. 8A). Then, the support substrate 90 is removed. The removal can be performed by grinding, for example, the support substrate 90. At this time the seed film 91 is also removed (FIG. 8B). After that, the solder balls 50 are formed on the lower surface of the package substrate (FIG. 9A). Finally, a dicing process is performed to obtain respective packages (FIG. 9B).

An effect of this embodiment will be described bellow. In the semiconductor device 1, the transmission line 30 provided on the package substrate 20 and the ground plane 46 provided in the dummy chip 40, which is mounted on the package substrate 20, constitute the microstrip line. Therefore, it is unnecessary to provide a ground plane, which constitutes the microstrip line, in the package substrate 20, so the number of interconnect layers of the package substrate 20 can decrease. In this embodiment, the number of interconnect layers is one, that is, the package substrate 20 is a single-layer substrate. According to this embodiment, even when a multilayer substrate is not used as the package substrate 20, excellent signal quality can be obtained by impedance matching.

As described above, the number of interconnect layers of the package substrate 20 is small, so a manufacturing cost of the package substrate 20 and thus a manufacturing cost of the semiconductor device 1 can be reduced. The package substrate 20 can be thinned, so heat generated by the semiconductor chip 10 can be efficiently diffused through the package substrate 20.

The ground plane 46 is provided in the dummy chip 40 mounted on the package substrate 20. In other word, the ground plane 46 is provided over the package substrate 20. Therefore, the structure in which the ground plane is provided over the package substrate 20 can be easily realized. The ground plane 46 is provided in not the semiconductor chip 10 but the dummy chip 40. This structure can prevent the ground plane 46 from having an adverse effect on operational characteristics of the semiconductor chip 10. In particular, when the semiconductor chip 10 is a memory chip, such an adverse effect can be easily produced.

The transmission line 30 includes the portion 30a for the microstrip line and the portion 30b for the coplanar line. Therefore, when the microstrip line and the coplanar line are combined with each other, impedance matching between the semiconductor chip 10 and the solder ball 50 can be suitably performed.

In the case where the ground plane 46 faces to only the portion of the transmission line 30 as in this embodiment, when the transmission line 30 including only the microstrip line is to be impedance-matched, it is necessary to further provide a ground plane to the package substrate 20. This is because the ground plane to constitute the microstrip line together with a remaining portion (that is, a portion which does not face to the ground plane 46) of the transmission line 30 is required. As a result, as in the case of JP 2003-282782 A, an increase in the number of interconnect layers of the interconnect substrate occurs.

On the other hand, when the transmission line 30 including only the coplanar line is to be impedance-matched, a ground potential becomes unstable because an area of the ground line 32 is smaller than that of the ground plane 46, so excellent signal quality cannot be stably obtained. Therefore, it is particularly preferable to perform impedance matching using a combination of the microstrip line and the coplanar line. When the ground plane 46 faces to the entire transmission line 30, the impedance matching may be performed using only the microstrip line.

A characteristic impedance of the transmission line is expressed by {(R+jωL)/(G+jωC)}^{1/2}. In recent years, although the number of signal lines is increased to realize a multifunctional LSI circuit, there is the tendency to reduce a package size. Therefore, an interval between transmission lines becomes smaller. Then, a capacitance value C increases and the characteristic impedance reduces. In order to hold the characteristic impedance to a constant value even when the interval between transmission lines is shortened, it is necessary to thin the transmission line to reduce the capacitance value C. However, when the transmission line is thinned, a cross sectional area of the transmission line becomes smaller, so a resistance value R increases. Therefore, a signal on the transmission line is significantly attenuated.

With respect to this point, in the case where the ground plane 46 provided outside the package substrate 20 is used as the ground plane for the microstrip line as in this embodiment, even when the package substrate 20 is thin, a distance between the ground plane 46 and the transmission line 30 can be lengthened. Therefore, it is unnecessary to thin the transmission line 30 to reduce the capacitance value C, so the resistance value R of the transmission line 30 can be suppressed to have a small value. Thus, a reduction in power consumption and an increase in signal transmission speed can be realized.

### Second Embodiment

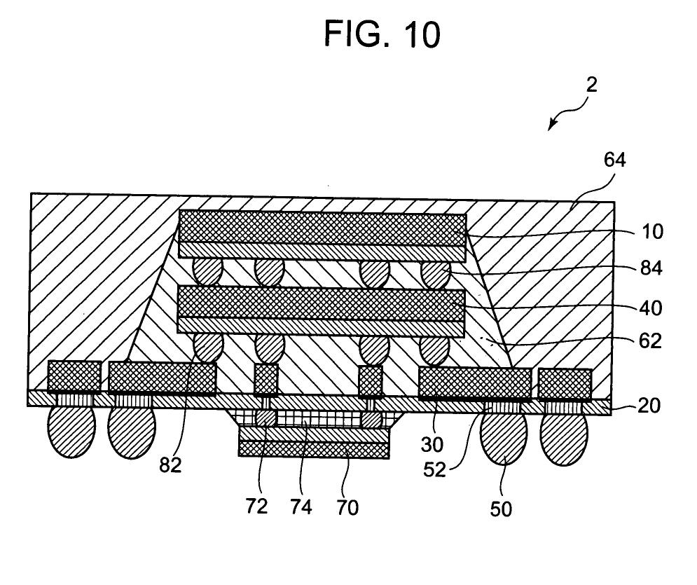

FIG. 10 is a cross sectional view showing a semiconductor device according to a second embodiment of the present invention. A basic structure of the semiconductor device 2 shown in FIG. 10 is approximately the same as the semiconductor device 1 described in the first embodiment. The semiconductor device 2 has the semiconductor chip 10 (first semiconductor chip) and a semiconductor chip 70 (second semiconductor chip). The semiconductor device 2 is different from the semiconductor device 1 in that a semiconductor chip 70 is mounted on the lower surface of the package substrate 20 through flip-chip bonding. In other words, the semiconductor chip 70 is mounted on the lower surface of the package substrate 20 through conductive bumps 72. The semiconductor chip 70 is electrically connected to the semiconductor chip 10 through the conductive bumps 72, the conductive plugs 52 and the conductive bumps 82. A gap between the semiconductor chip 70 and the package substrate 20 is filled with an underfill resin 74.

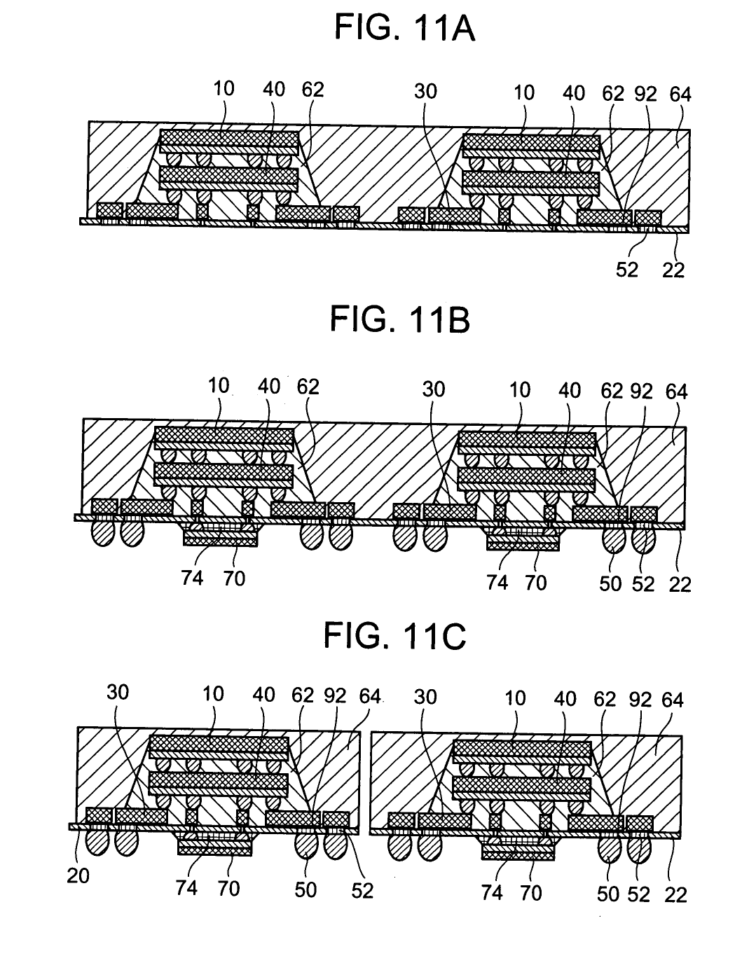

An example of a method for manufacturing the semiconductor device 2 will be described with reference to FIGS. 11A to 11C. An explanation of the same manufacturing process as the first embodiment will be omitted.

The manufacturing process from the seed film formation (FIG. 5A) to the seal resin formation (FIG. 8A) is basically the same as the first embodiment.

After the seal resin 64 is formed so as to cover the semiconductor chip 10 and the dummy chip 40, the support substrate 90 is removed (FIG. 11A). The removal can be performed by grinding, for example, the support substrate 90. At this time the seed film 91 is also removed (FIG. 11A). After that, the semiconductor chip 70 is mounted on a lower surface of the insulating film 22 through a flip-chip bonding and a gap between the semiconductor chip 70 and the package substrate is filled with the underfill resin 74 (FIG. 11B). Finally, a dicing process is performed to obtain respective packages (FIG. 11B).

### Third Embodiment

FIG. 12 is a cross sectional view showing a semiconductor device according to a third embodiment of the present invention. A basic structure of the semiconductor device 3 shown in FIG. 12 is approximately the same as the semiconductor device 1 described in the first embodiment. The semiconductor device 3 is different from the semiconductor device 1 in that a semiconductor chip 70 is mounted on the lower surface of the package substrate 20 through flip-chip bonding, and the semiconductor chip 10 comprises a plurality of semiconductor chips which are stacked on the dummy chip 40.

The plurality of semiconductor chips 10 are provided and stacked on each other. A gap between a lowermost one of the semiconductor chips 10 and the dummy chip 40 and a gap between adjacent two of the semiconductor chips 10 are filled with the underfill resin 62. A seal resin 64 is provided to cover the semiconductor chips 10 and the dummy chip 40.

In this embodiment, a semiconductor chip 70 is mounted on the lower surface of the package substrate 20 through flip-chip bonding. In other words, the semiconductor chip 70 is mounted on the lower surface of the package substrate 20 through conductive bumps 72. A gap between the semiconductor chip 70 and the package substrate 20 is filled with an underfill resin 74.

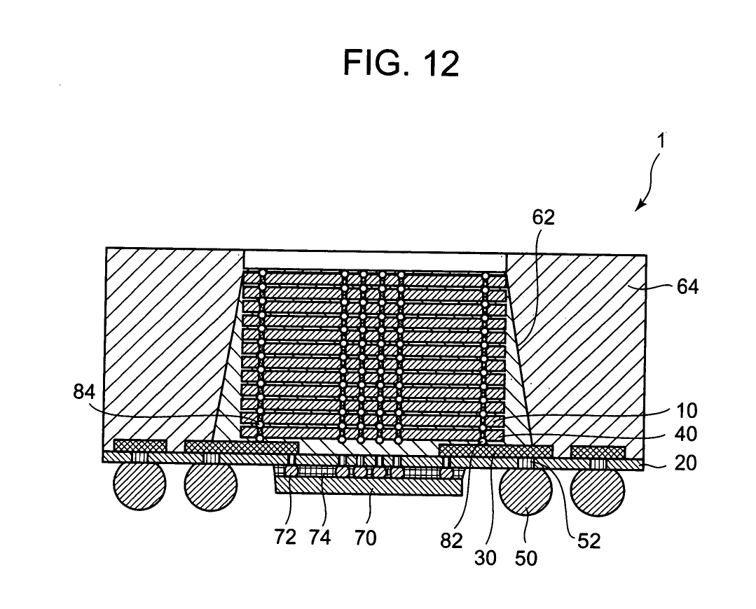

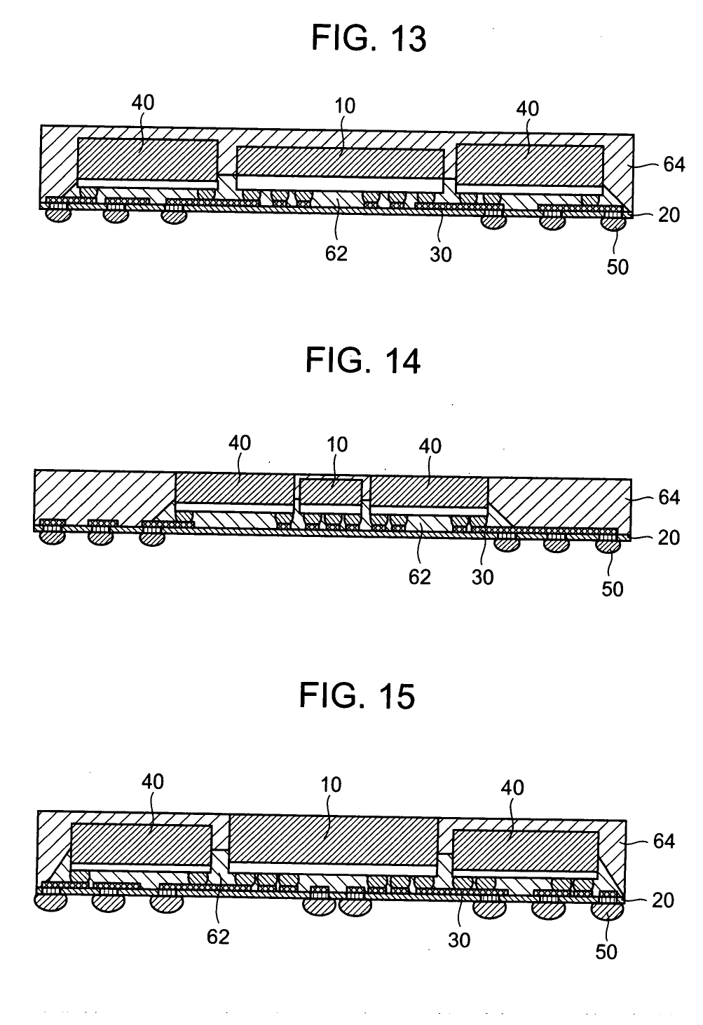

The present invention is not limited to the above-mentioned embodiment and thus various modifications can be made. For example, the semiconductor chip 10 is mounted on the dummy chip 40 in the first, the second, and the third embodiment. However, as shown in FIGS. 13 to 18, the semiconductor chip 10 and the dummy chips 40 may be mounted in different regions on the upper surface of the package substrate 20. In FIG. 13, both the rear surface of the semiconductor chip 10 and the rear surface of the dummy chips 40 are covered with the seal resin 64. In FIG. 14, although the rear surface of the semiconductor chip 10 is covered with the seal resin 64, the rear surface of the dummy chips 40 is exposed. In FIG. 15, although the rear surface of the semiconductor chip 10 is exposed, the rear surface of the dummy chips 40 is covered with the seal resin 64.

The portion 30b and ground lines 32, which is provided on the upper surface of the package substrate 20, constitute the coplanar line. The transmission line 30 further includes a connection portion 31a with respect to one of the conductive bumps 82 and a connection portion 31b with respect to one of the conductive plugs 52. Each of the ground lines 32 includes a connection portion 33a with respect to another one of the conductive bumps 82 and a connection portion 33b with respect to another one of the conductive plugs 52.

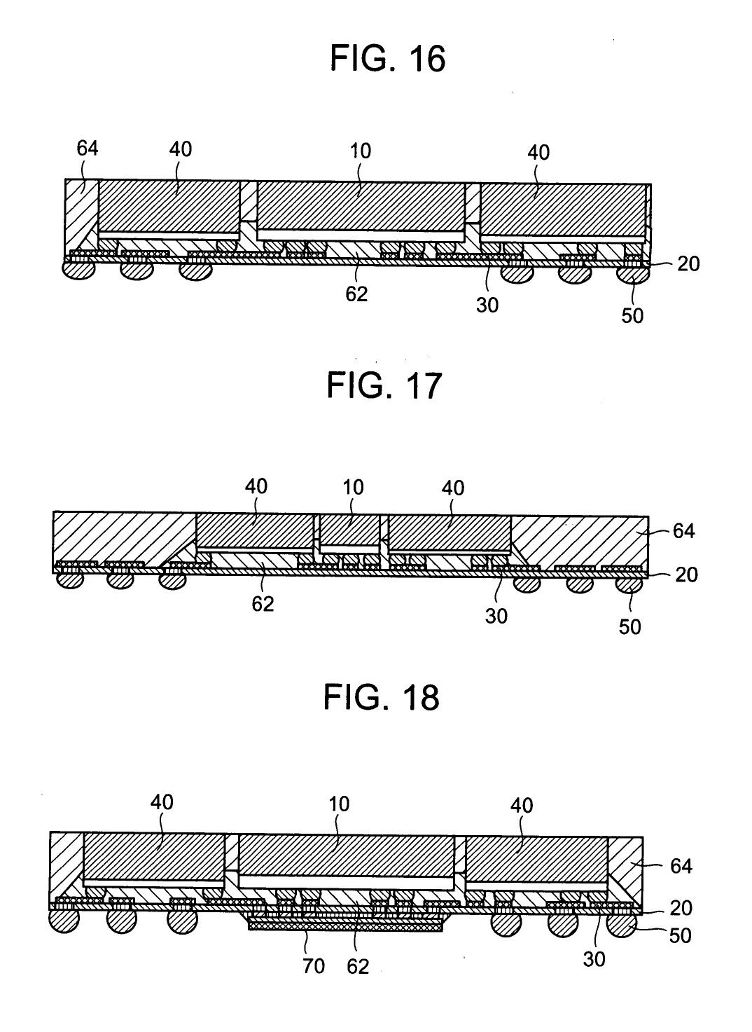

In each of FIGS. 16 to 18, both the rear surface of the semiconductor chip 10 and the rear surface of the dummy chips 40 are exposed. In FIG. 17, in particular, the semiconductor chip 10 and the dummy chips 40 are provided in regions so as not to overlap with the solder balls 50 from a two-dimensional viewpoint. With such a structure, another semiconductor chip can be mounted on the lower surface of the package substrate 20 in a region located just under the semiconductor chip 10 and the dummy chips 40. The same applies to the case of FIG. 14. In FIG. 18, the semiconductor chip 70 is mounted on the lower surface of the package substrate 20.

When the rear surface of the semiconductor chip 10 is exposed as shown in each of FIGS. 15 to 18, heat generated by the semiconductor chip 10 can be efficiently diffused from the rear surface thereof. When the rear surface of the dummy chip 40 is exposed as shown in each of FIGS. 14, 16, 17, and 18, the heat generated by the semiconductor chip 10 can be efficiently diffused through the dummy chip 40.

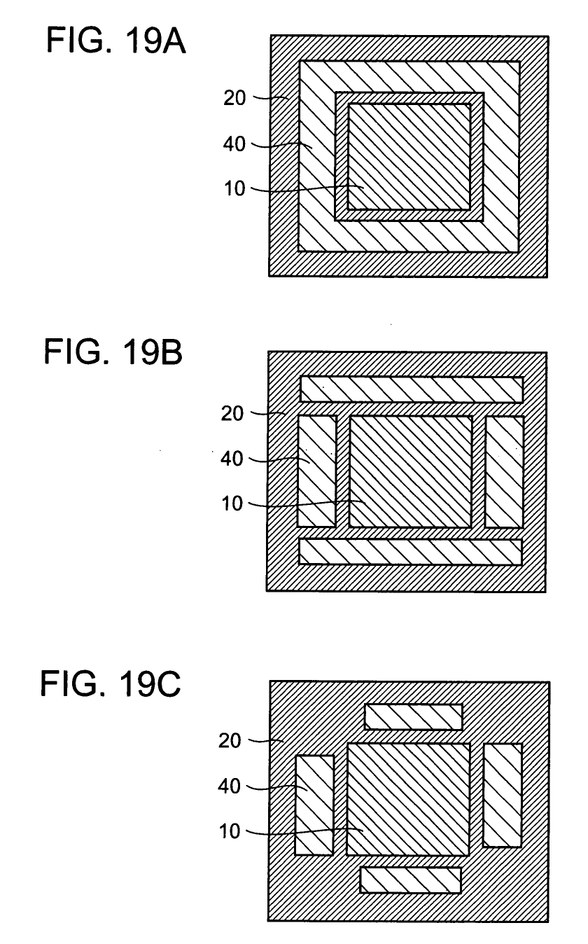

Various two-dimensional layouts of the dummy chip 40 are expected. For example, in FIGS. 19A to 19C, the at least one dummy chip 40 is disposed along all four sides of the semiconductor chip 10. In FIG. 19A, in particular, the dummy chip 40 is formed in a loop shape to surround the semiconductor chip 10. In FIG. 19B, the dummy chip 40 whose length is substantially equal to that of a first pair of opposed sides of the semiconductor chip 10 is disposed along each of the opposed sides thereof. In addition, the dummy chip 40 whose length is longer than that of a second pair of opposed sides of the semiconductor chip 10 is disposed along each of the opposed sides thereof. In FIG. 19C, the dummy chip 40 whose length is shorter than that of sides of the semiconductor chip 10 is disposed along each of the sides thereof.

As described above, when at least one dummy chip 40 is disposed along the four sides of the semiconductor chip 10, a degree of flatness on a package surface can be improved. It is likely that a height of the package surface in a region, in which the dummy chip 40 is not provided, will become lower than that in a region in which the dummy chip 40 is provided. However, when at least one dummy chip 40 is disposed along the four sides of the semiconductor chip 10, the occurrence of the adverse effect can be suppressed.

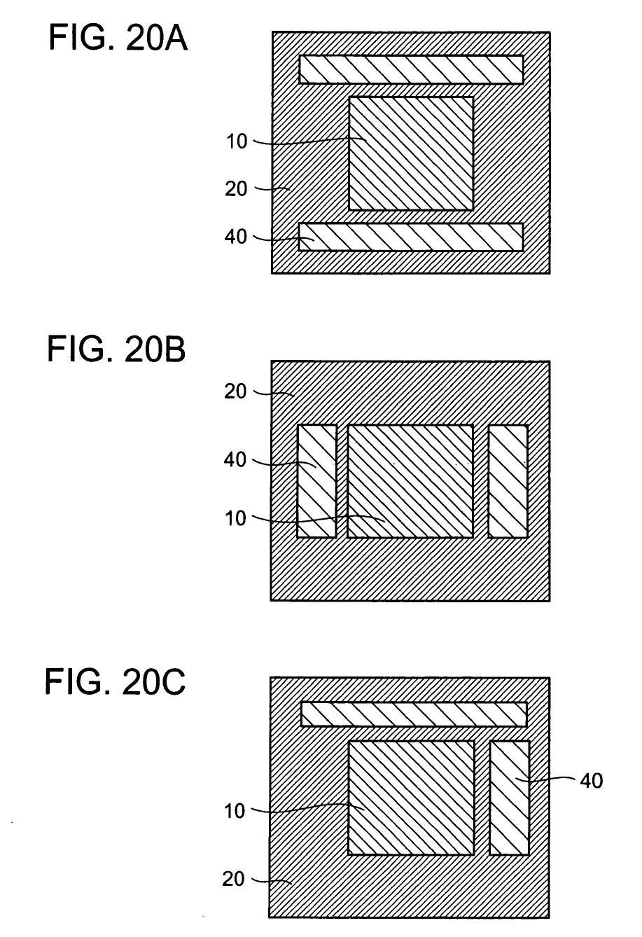

As shown in FIGS. 20A to 20C, the dummy chips 40 may be disposed along two of the four sides of the semiconductor chip 10. In FIG. 20A, the dummy chip 40 whose length is longer than that of a pair of-opposed sides of the semiconductor chip 10 is disposed along each of the opposed sides thereof. In FIG. 20B, the dummy chip 40 whose length is substantially equal to that of a pair of opposed sides of the semiconductor chip 10 is disposed along each of the opposed sides thereof. In FIG. 20C, the dummy chip 40 whose length is substantially equal to that of a first side of the semiconductor chip 10 is disposed along the first side thereof. In addition, the dummy chip 40 whose length is longer than that of a second side adjacent to the first side is disposed along the second side.

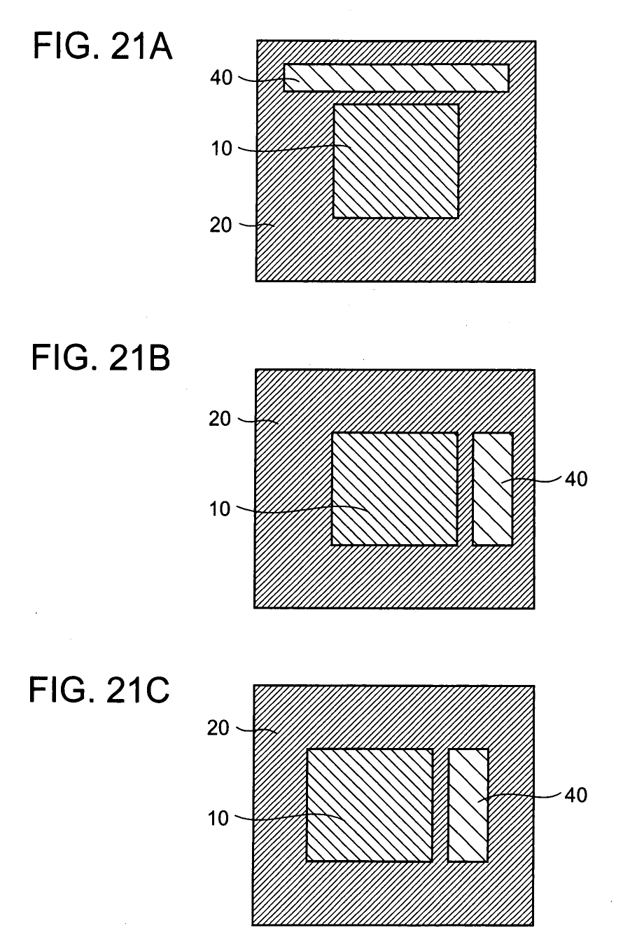

Alternatively, as shown in FIGS. 21A to 21C, the dummy chip 40 may be disposed along one of the four sides of the semiconductor chip 10. In FIG. 21A, the dummy chip 40 whose length is longer than that of one of the sides of the semiconductor chip 10 is disposed along the one of the sides thereof. In each of FIGS. 21B and 21C, the dummy chip 40 whose length is substantially equal to that of one of the sides of the semiconductor chip 10 is disposed along the one of the sides thereof. In FIG. 21C, in particular, a distance between a side of the dummy chip 40 which is opposed to the semiconductor chip 10 and a package side surface is substantially equal to a distance between a side of the semiconductor chip 10 which is opposed to the dummy chip 40 and a package side surface. Although not shown, the dummy chips 40 may be disposed along three of the four sides of the semiconductor chip 10.

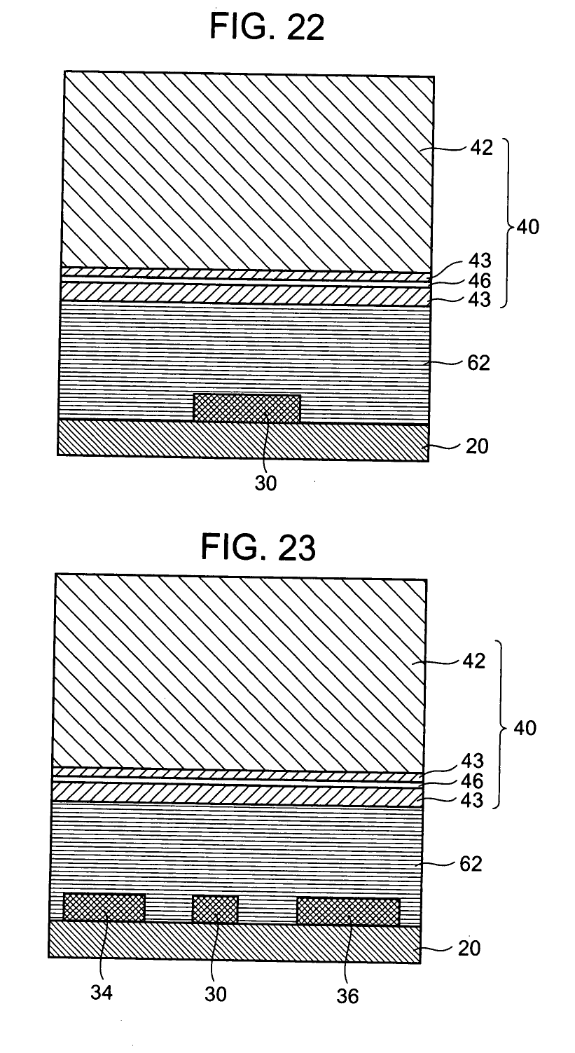

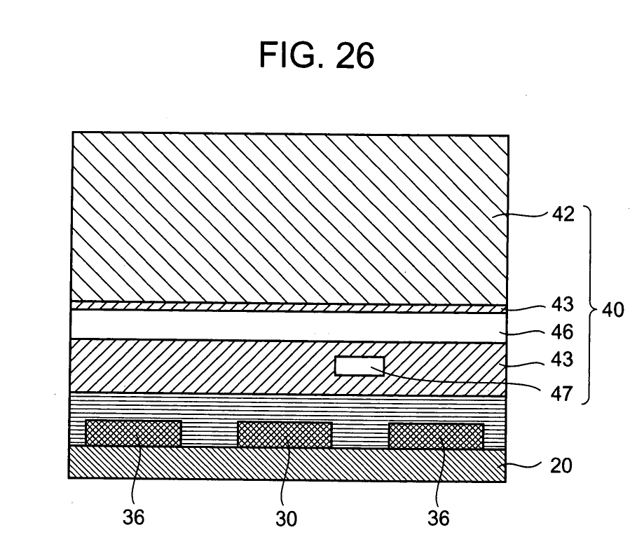

Various structures of the dummy chip 40 are expected and examples thereof are shown in FIGS. 22 to 26. In each of FIGS. 22 and 26, the ground plane 46 is provided over the entire surface of the silicon substrate 42. In FIG. 23, in particular, a power supply line 34 and a ground line 36 are provided in the same layer as the transmission line 30. In FIG. 24, a signal line 47 is provided in the same layer as the ground plane 46. Therefore, when the ground plane 46 and the signal line 47 are disposed in the same layer, the number of layers of the dummy chip 40 can be reduced.

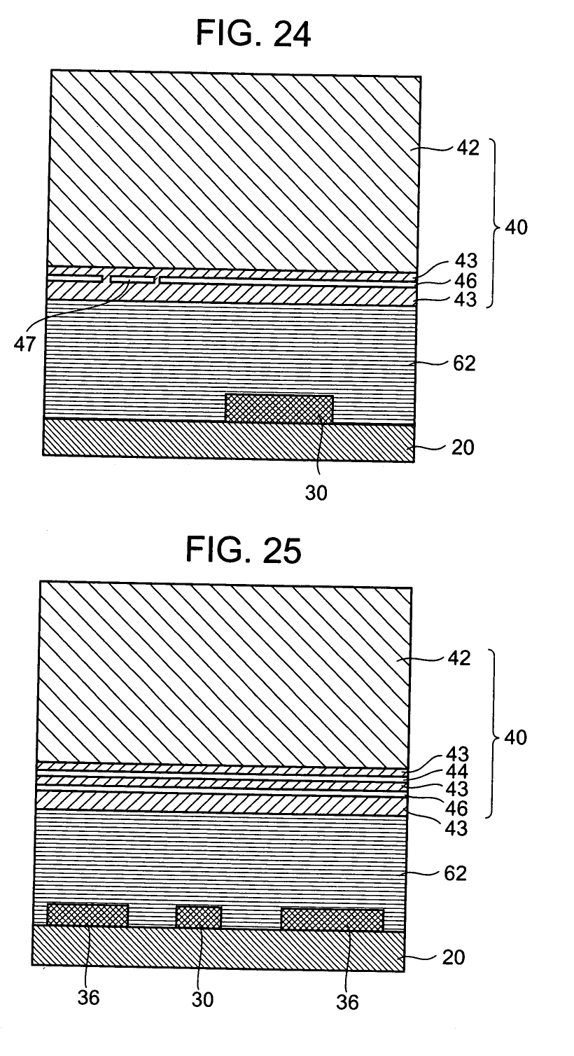

In FIG. 25, the power supply plane 44 and the ground plane 46 are provided between the insulating layers 43. The power supply plane 44 and the ground plane 46 compose a capacitive element together with one of the insulating layers 43 which is sandwiched therebetween. In FIG. 26, the signal line 47 is provided in a different layer from the ground plane 46 in the insulating layer 43.

In the above-mentioned embodiment, the ground plane 46 is provided in the dummy chip 40. However, when the ground plane 46 is located over the upper surface of the package substrate 20, the ground plane 46 may be provided to a circuit component other than the dummy chip 40 or separately provided. An example of the circuit component other than the dummy chip 40 includes the semiconductor chip 10.

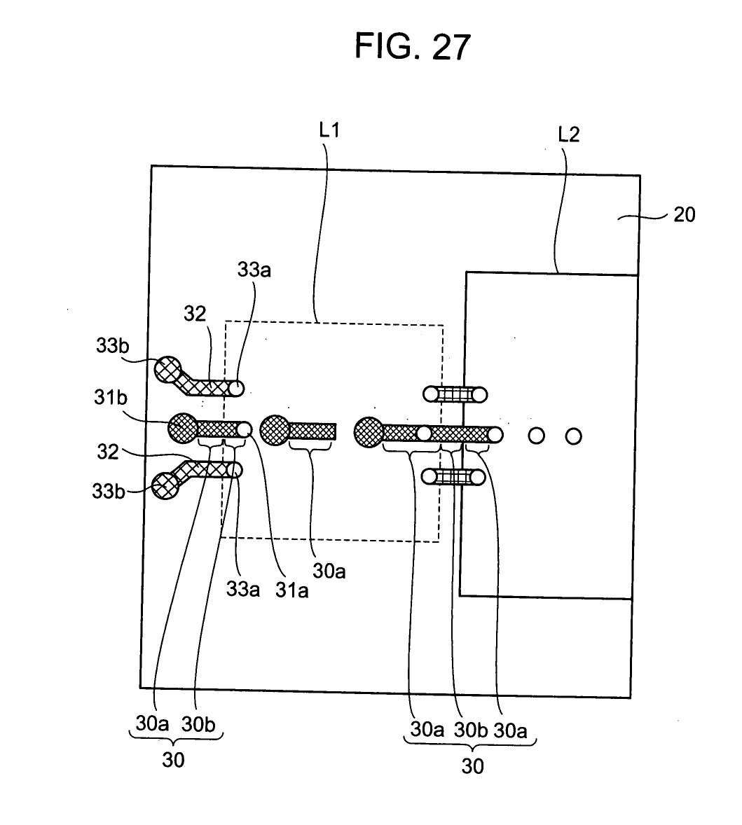

For example, in FIG. 13, the semiconductor chip 10 also has a ground plane therein. FIG. 27 is a schematic diagram of a plan view illustrating a part of an interconnect substrate shown in FIG. 13. In FIG. 27, an outer shape of the dummy chip 40 is expressed by a dotted line L1, and an outer shape of the semiconductor chip 10 is expressed by a solid line L2. The transmission line 30 includes a portion 30a for a microstrip line and a portion 30b for a coplanar line. The microstrip line 30a is provided in both of an area surrounded by L1 and an area surrounded by L2.

In the above-mentioned embodiment, the example of the package substrate 20 is the single-layer substrate. The package substrate 20 may be a multilayer substrate. The number of layers of the package substrate 20 is preferably equal to or smaller than two.

What is claimed is:

1. A semiconductor device, comprising:
an interconnect substrate having a main surface;
a transmission line which is provided on the main surface of the interconnect substrate; and
a circuit component which is mounted over the main surface of the interconnect substrate and includes a ground plane,
wherein at least a part of the transmission line and the ground plane constitute a microstrip line.

2. The semiconductor device according to claim 1, further comprising a ground line provided on the main surface of the interconnect substrate,
wherein the transmission line comprises a first portion and a second portion that is connected to the first portion, the first portion and the ground plane constituting the microstrip line, the second portion and the ground line constituting a coplanar line.

3. The semiconductor device according to claim 2, wherein the ground plane faces to only the first portion of the transmission line.

4. The semiconductor device according to claim 2, wherein the main surface of the interconnect substrate is a first main surface and the interconnect substrate further comprises a second main surface opposing to the first main surface, and
wherein a ground plane is not provided under the second main surface.

5. The semiconductor device according to claim 2, wherein the ground plane is coupled to the ground line.

6. The semiconductor device according to claim 1, wherein the circuit component is mounted on the main surface of the interconnect substrate through flip-chip bonding.

7. The semiconductor device according to claim 1, wherein the circuit component is a dummy chip.

8. The semiconductor device according to claim 6, further comprising a semiconductor chip mounted on the circuit component through flip-chip bonding.

9. The semiconductor device according to claim 8, wherein the semiconductor chip comprises a plurality of semiconductor chips which are stacked.

10. The semiconductor device according to claim 1, further comprising:
a first semiconductor chip; and
a second semiconductor chip,
wherein the main surface of the interconnect substrate is a first main surface and the interconnect substrate further comprises a second main surface opposing to the first main surface, and
wherein the first semiconductor chip is mounted on the first main surface and the second semiconductor chip is mounted on the second surface of the interconnect substrate.

11. The semiconductor device according to claim 10, further comprising a conductive plug extending through the interconnect substrate,
wherein the second semiconductor chip is coupled to the first semiconductor chip by the conductive plug.

12. The semiconductor device according to claim 1, further comprising a semiconductor chip,
wherein the semiconductor chip and the circuit component are mounted in different areas on the main surface of the interconnect substrate.
